(19) United States
(12) Patent Application Publication
(10) Pub. No.: US 2014/0321097 A1
(43) Pub. Date: Oct. 30, 2014

(54) ELECTROMAGNETIC EMISSION SHIELD WITH SUBSTRATE REINFORCEMENT FEATURES

(71) Applicant: MOTOROLA MOBILITY LLC, Libertyville, IL (US)

(72) Inventors: Tyler D. McLean, Chicago, IL (US); John Delianides, Lake Villa, IL (US)

(73) Assignee: MOTOROLA MOBILITY LLC, Libertyville, IL (US)

(21) Appl. No.: 13/869,042

(22) Filed: Apr. 24, 2013

(51) Int. Cl. H05K 9/00; H05K 3/30

(52) U.S. Cl. CPC H05K 9/00; H05K 3/30
USPC 361/818; 29/832

(57) ABSTRACT

An assembly (600) includes a substrate (601), an electrical component (1202), and a shield (400). The electrical component is disposed beneath the shield, with both being coupled to a major face (602) of the substrate. The shield can include an upper surface (401) including one or more indentations (408,409) disposed above, and extending toward, the electrical component. A shim (1106) or an injected material (1209) can be substituted for, or used with, the indentations.

### BACKGROUND

1. Technical Field

This disclosure relates generally to an electromagnetic shield, and more particularly to an electromagnetic shielding assembly for electronic devices.

2. Background Art

Electromagnetic shields are frequently found in radio frequency (RF) electronic devices or in other devices that may be sensitive to electromagnetic emissions. Shields are commonly used to isolate sensitive components residing on a circuit board. Prior art shields are made from a metal or metallized member that has a planar top surface and planar sidewalls extending orthogonally from each edge of the top surface. The bottom ends of the sidewalls may include feet or flanges so that the shield can be soldered to the circuit board.

Prior art shields generally lack mechanical strength when the circuit board is subjected to mechanical loading, such as bending loads, torsional loads and plane loads. When this occurs, the performance reliability of the shield can be compromised. The solder connection between the shield and the circuit board can break, thereby reducing the ability of the shield to isolate sensitive components from electromagnetic radiation.

Even when the shield includes some mechanical strength, the circuit board can still flex under mechanical loading. The circuit board can act as the webbing of a trampoline with the shield acting as the mechanical support of the trampoline. Deflection of the circuit board can cause strain, damage components, and break electrical connections, just to name a few of the maladies that can result.

It would be advantageous to have an improved shielding assembly for electronic devices.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present disclosure.

FIG. 1 illustrates a perspective view of a prior art shield.

FIG. 2 illustrates a sectional, elevation view of a prior art shield.

FIG. 3 illustrates a sectional, elevation view of a prior art shield when the printed circuit board is subjected to mechanical loading.

FIG. 4 illustrates an explanatory shield configured in accordance with one or more embodiments of the disclosure.

FIG. 5 illustrates a plan view of an explanatory shield configured in accordance with one or more embodiments of the disclosure.

FIG. 6 illustrates a sectional, elevation view of an explanatory shield configured in accordance with one or more embodiments of the disclosure.

FIG. 7 illustrates a sectional, elevation view of an explanatory shield configured in accordance with one or more embodiments of the disclosure when the printed circuit board is subjected to mechanical loading.

FIG. 8 illustrates an explanatory shield configured in accordance with one or more embodiments of the disclosure in illustrative packaging.

FIGS. 9 and 10 illustrate another explanatory shield configured in accordance with one or more embodiments of the disclosure.

FIG. 11 illustrates a sectional, elevation view of another explanatory shield configured in accordance with one or more embodiments of the disclosure.

FIG. 12 illustrates a sectional, perspective view of another explanatory shield configured in accordance with one or more embodiments of the disclosure.

FIG. 13 illustrates a method in accordance with one or more embodiments of the disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

### DETAILED DESCRIPTION OF THE DRAWINGS

Embodiments of the disclosure are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions. Also, reference designators shown herein in parenthesis indicate components shown in a figure other than the one in discussion. For example, talking about a device (10) while discussing figure A would refer to an element, 10, shown in figure other than figure A.

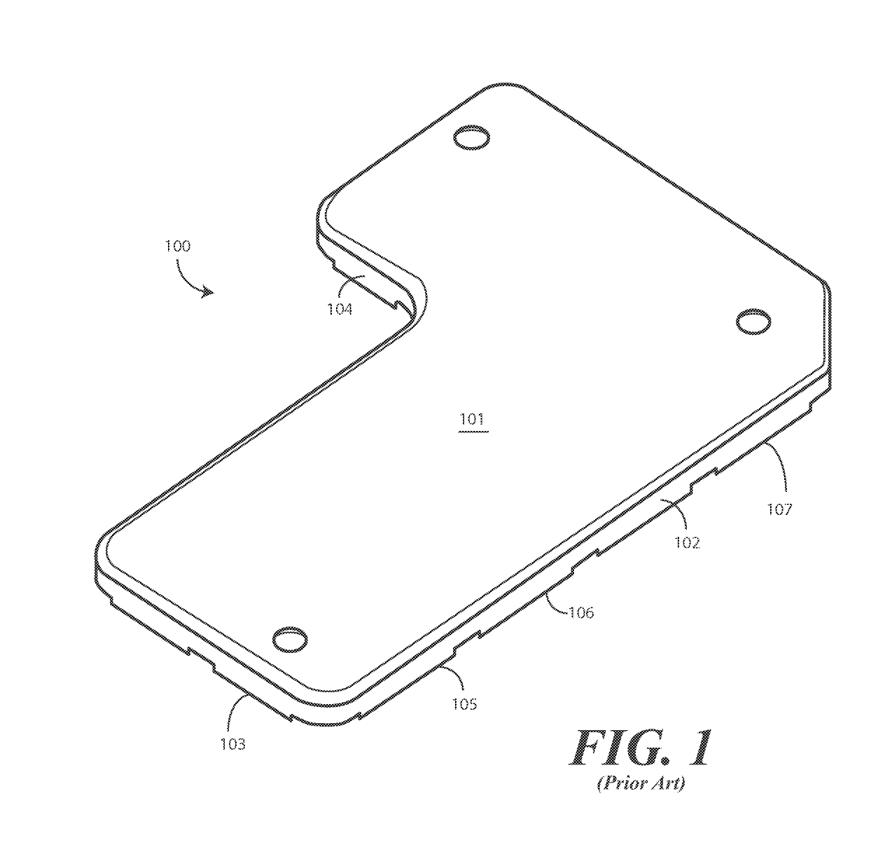

Turning to FIG. 1, illustrated therein is a prior art shield 100. As shown, the prior art shield 100 has a planar top surface 101 and planar sidewalls 102,103,104 extending orthogonally from each edge of the planar top surface 101. This particular prior art shield 100 includes flanges 105,106,106 so that the prior art shield 100 can be soldered to a circuit board.

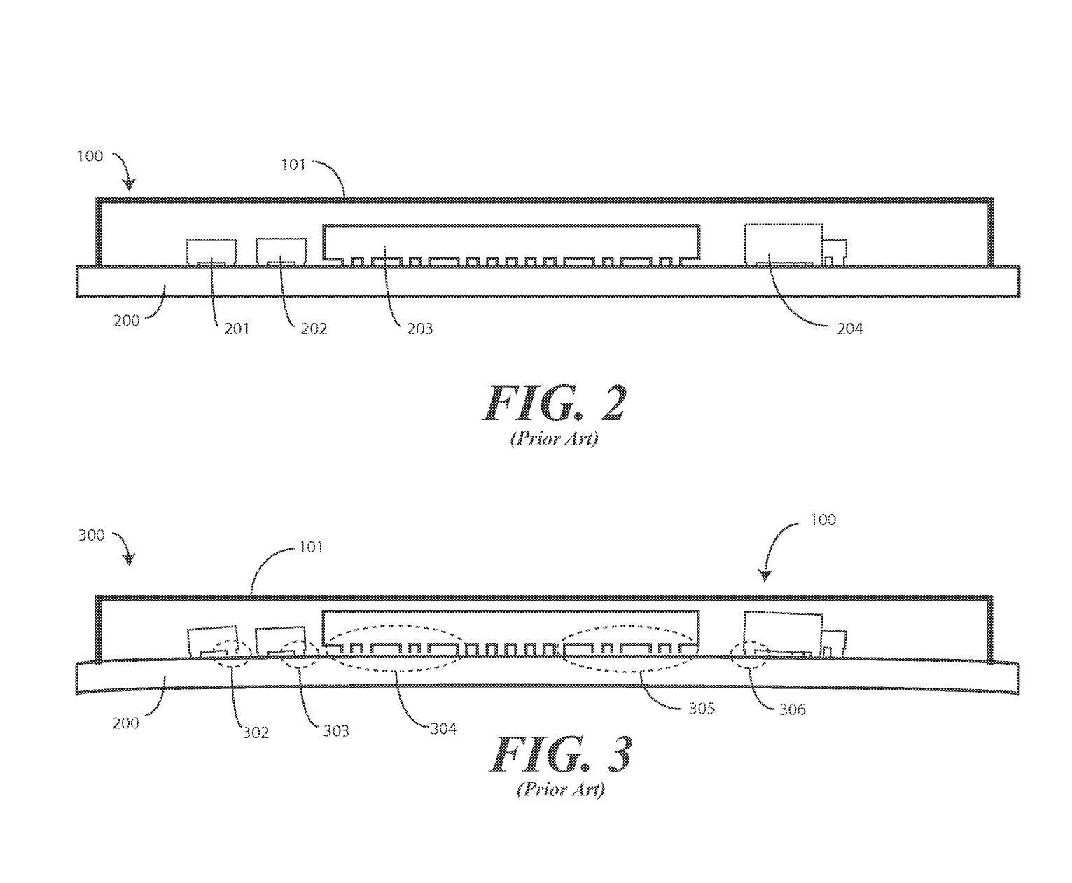

Turning to FIG. 2, illustrated therein is the prior art shield 100 coupled to a printed circuit board 200. The planar top surface 101 covers several electrical components 201,202,203,204.

Turning to FIG. 3, the circuit board 200 is being subjected to mechanical loading. As shown at point 301, this causes the circuit board 200 to flex. The prior art shield 100, being manufactured from a thick metal, remains rigid. Accordingly, the assembly 300 functions like an inverted trampoline, with the prior art shield 100 serving as the trampoline frame, and the circuit board 200 serving as the trampoline mat. Each of the electrical components 201,202,203,204 translates vertically toward the planar top surface 101 of the prior art shield 100, thereby causing electrical connections to be broken at points 302,303,304,305,306. This “trampoline effect” renders the assembly 300 non-functional.

Embodiments of the present disclosure serve to prevent the trampoline effect by providing a shield with increased mechanical structure and with features that limit the vertical translation that a substrate can make, thereby reducing or preventing damage. In one embodiment, a shield is disposed along the major face of a circuit substrate. The shield can enclose one or more electrical components. In one embodiment, the shield has an upper surface comprising one or more indentations disposed above, and extending from the upper surface of the shield toward the electrical components covered by the indentation.

In one embodiment, each indentation has a length and a width that corresponds to that of the electrical component the indentation covers. A single indentation can cover multiple electrical components in one embodiment. Alternatively, the indentations can correspond to electrical components on a one-to-one basis.

In one embodiment, each indentation is substantially rectangular. In other embodiments, the indentations can take other shapes, including circular, triangular, polygonal, free form, and so forth. The shape of the indentations can be determined from the application or device with which the shield is used.

In one embodiment, the indentation has a bottom surface disposed adjacent to an upper face of the electrical component it covers. Accordingly, the bottom surface of the indentation can serve as a mechanical stop for the electrical component that limits the vertical translation that occurs when the substrate is subjected to mechanical loading. In one embodiment, the bottom surface of the indentation and the upper face of the electrical component define a gap therebetween when the shield is installed. This gap is significantly narrower than that established between electrical components and prior art shields. For example, in one embodiment the gap defined with shields configured in accordance with embodiments of the disclosure is between 0.05 and 0.10 millimeters, such as 0.08 millimeters. This gap, in one embodiment, is less than 20% of the gap defined by prior art shields. Advantageously, this reduced gap limits translation of the substrate and electrical components during mechanical reloading. This reduced translation prevents the shield from disconnecting from the substrate, prevents electrical connections from being broken, and prevents damage to sensitive components.

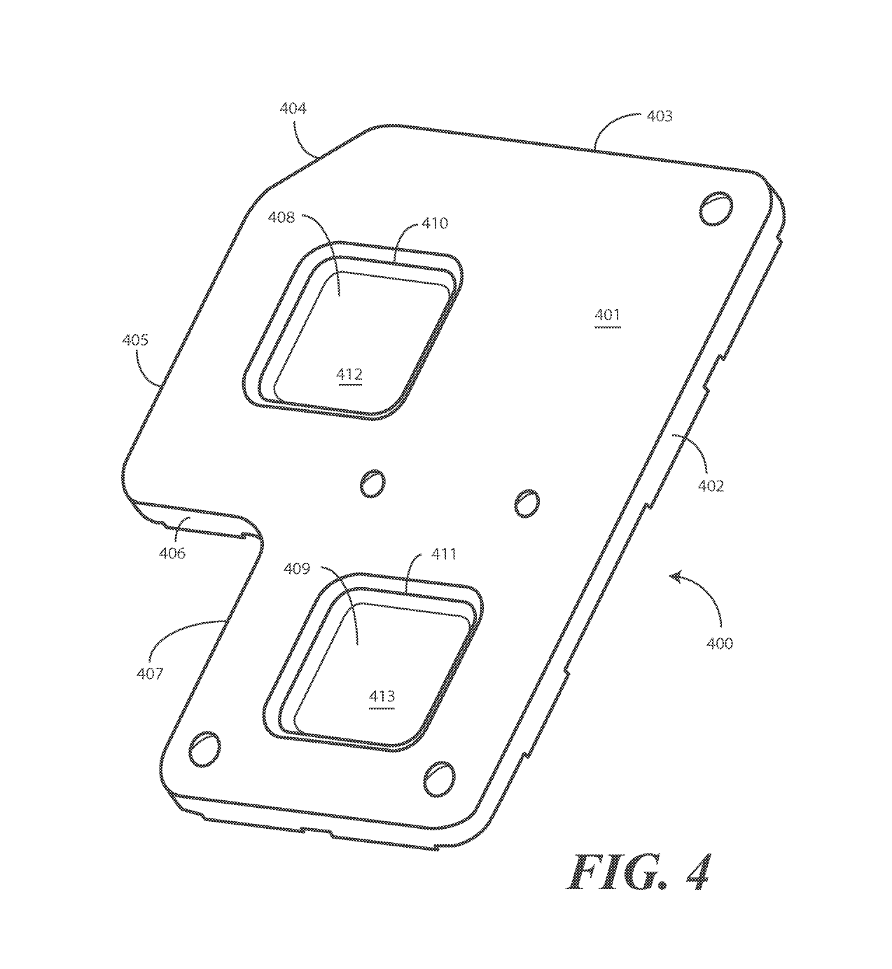

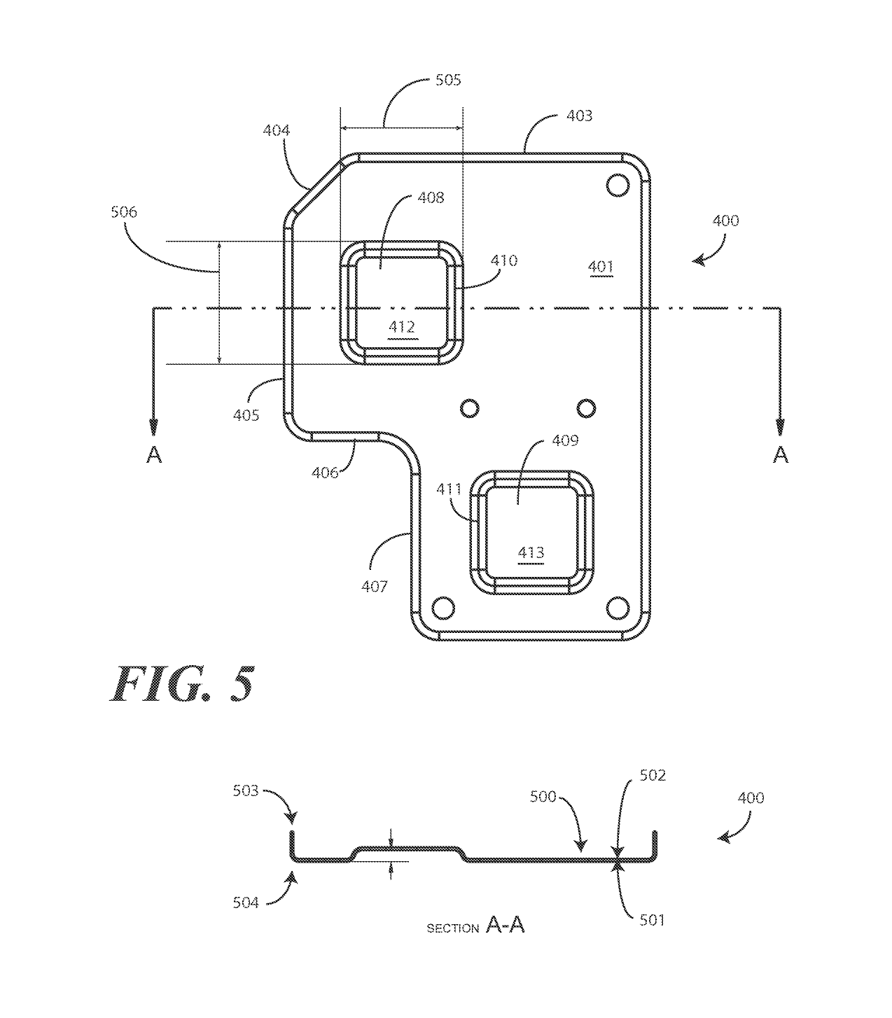

Turning now to FIGS. 4 and 5, illustrated therein is a shield 400 configured in accordance with one or more embodiments of the disclosure. The explanatory shield 400 can be used to shield integrated circuits or other electronic components from electromagnetic emissions. The shield 400 can be soldered or otherwise coupled to a circuit substrate so as to cover the shielded electronic components. The shield 400 is suitable for use in many different types of electronic devices. Illustrating by example, the shield 400 can be used in mobile communication devices, such as smartphones, tablet computers, and so forth. Those of ordinary skill in the art having the benefit of this disclosure will understand that mobile communication devices are merely one type of electronic device for which the shield 400 is suited, and are being used purely for illustrative purposes. Shields configured in accordance with one or more embodiments of the disclosure are certainly usable and compatible with any number of different structures and devices.

In one embodiment, the shield 400 is manufactured from a sheet metal frame. For example, in one embodiment, the shield 400 can be machine formed from cold rolled steel. In other embodiments, the shield 400 can be manufactured from cast metal. Other materials and methods of manufacture for the shield will be obvious to those of ordinary skill in the art having the benefit of this disclosure.

The explanatory shield 400 of FIGS. 4 and 5 is shown as comprising an upper surface 401 and sidewall assembly 402. The upper surface 401 and sidewall assembly 402 define a cavity 500. The cavity 500 can be configured to enclose electrical components disposed beneath the shield 400. The upper surface 401 includes a top surface 501, a bottom surface 502, and an outer perimeter 403. The outer perimeter 403 of this explanatory embodiment includes a number of edges or segments, e.g., segments 404,405,406,407. In this illustrative embodiment, these segments 404,405,406,407 comprise a plurality of substantially linear edges with radiused corners therebetween. As seen best in FIG. 5, this illustrative shield 400 is configured as an angularly truncated, inverted L-shape, as segment 404 truncates the horizontal extension of the inverted-L shape defined by the upper surface 401. In one embodiment, the upper surface 401 is of a substantially uniform thickness.

In one embodiment, the sidewall assembly 402 includes a plurality of sidewalls that extend substantially orthogonally from the upper surface 401 about the outer perimeter 403. In one embodiment, the sidewall assembly 402 includes proximal end 504 and distal end 503. The distal end 503 terminates at a lower edge. In one embodiment, the length and width of the upper surface 401 are substantially larger than the height of the sidewall assembly 402, i.e., the distance between the proximal end 504 and the distal end 503.

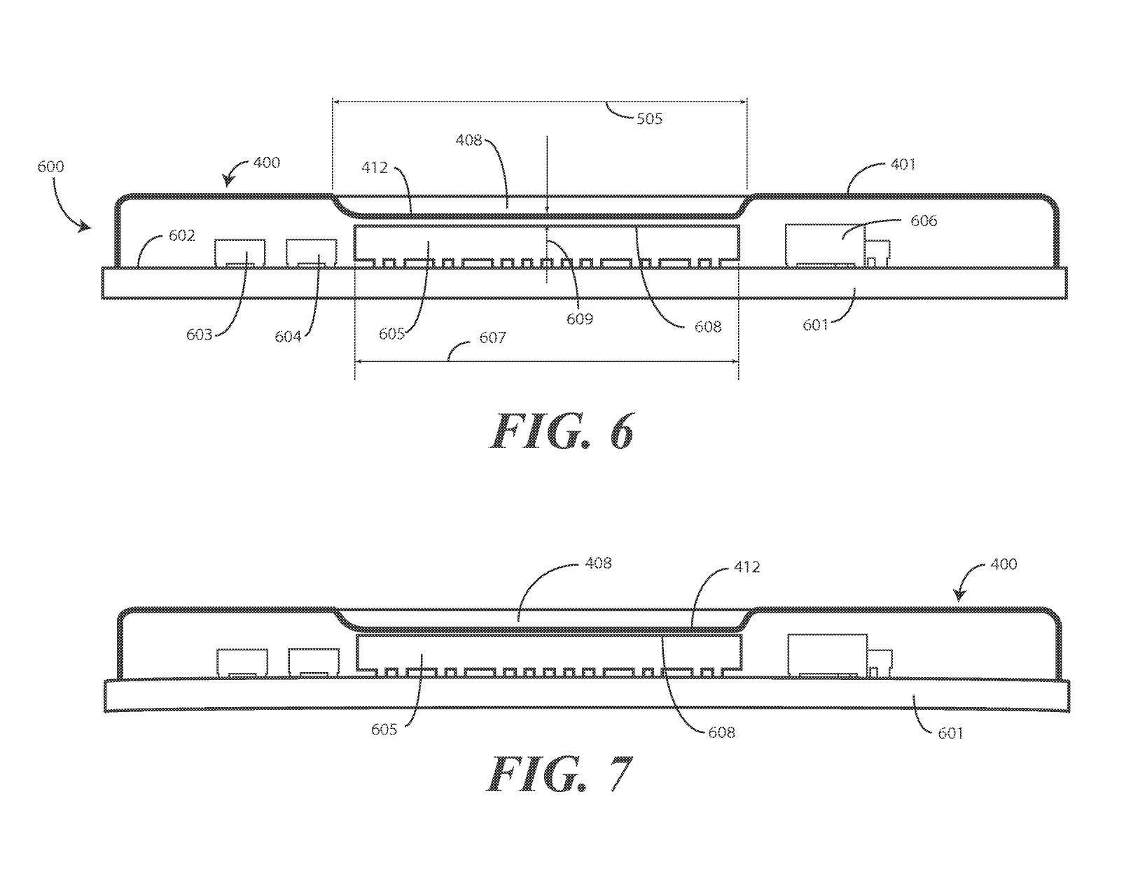

In one embodiment, the upper surface 401 comprises one or more indentations 408,409. As will be described in more detail below with reference to FIG. 6, in one embodiment the indentations 408,409 are configured to be disposed above, and extending from the upper surface 401 toward one or more electrical components disposed beneath the shield 400.

In the illustrative embodiment of FIGS. 4 and 5, each indentation 408,409 has a substantially rectangular perimeter with radiused corners. As noted above, in other embodiments, the indentations can take other shapes, including circular, triangular, polygonal, free form, and so forth. The shape of the indentations can be determined from the application or device with which the shield is used.

In the illustrative embodiment of FIGS. 4 and 5, two indentations 408,409 are shown. The illustrative shield 400 shown is to be used with two processing circuits, with each indentation 408,409 corresponding to a processing circuit on a one-to-one basis. In other embodiments, the indentations 408,409 can be configured to cover multiple components rather than a single one.

In the illustrative embodiment of FIGS. 4 and 5, each indentation 408,409 has a radiused sidewall 410,411 that terminates at a bottom surface 412,413. In this explanatory embodiment, the bottom surface 412,413 of each indentation 408,409 is substantially planar. However, in other embodiments, the bottom surface 412,413 can be contoured so as to resemble the surface of the electrical component(s) it is designed to cover.

In an embodiment suitable for use with processing circuits in a smart phone, each indentation 408,409 has a width 505 of between five and six millimeters and a length 506 of between five and six millimeters. For example, in one embodiment the indentations 408,409 are substantially square, with a side dimension of about 5.78 millimeters excluding manufacturing tolerances. These dimensions are illustrative only, as the shield 400 and indentations are readily scalable to any size.

In the illustrative embodiment of FIGS. 4 and 5, the upper surface 401 includes two indentations 408,409. However, it will be obvious to those of ordinary skill in the art having the benefit of this disclosure that embodiments are not so limited. Shields configured in accordance with embodiments of the disclosure can be configured with one, three, four, or more indentations. Moreover, while the shield 400 of this embodiment is shown having indentations 408,409 that extend into the cavity 500 away from the upper surface 401 toward the distal end 503 of the sidewall assembly 402, it should be noted that these mechanical features can alternatively be configured as protrusions as well. Further, combinations of indentations and protrusions can be used to accommodate a variety of electronic component heights.

Turning now to FIG. 6, illustrated therein is one explanatory assembly 600 including a shield 400 configured in accordance with one or more embodiments. As shown in FIG. 6, the assembly 600 includes the shield 400 of FIGS. 4 and 5. The shield 400 has been coupled to a circuit substrate 601. In this illustrative embodiment, the shield 400 has been soldered to exposed metal pads on the circuit substrate 601.

At least one electrical component is disposed along a major face 602 of the substrate 601. In this embodiment, four electrical components are shown. They include a pair of decoupling capacitors 603,604, an integrated circuit processor 605, and an application specific integrated circuit 606. These components are illustrative only. One point of note is that the integrated circuit processor 605 is substantially wider than the other components. Accordingly, the designer of this assembly 600 has elected to provide an indentation 408 only above this component due to the fact that the others are significantly smaller in size.

As can be seen in this figure, the indentation 408 is disposed above, and extends from the upper surface 401 of the shield 400 toward the integrated circuit processor 605. In this explanatory embodiment, the indentation has a length (506) and width 505 that correspond to the width and length of the integrated circuit processor 605. This can be seen as the width 505 of the indentation 408 is substantially the same as the width 607 of the integrated circuit processor 605. In other embodiments, the dimensions of the indentation 408 can differ from that of the electronic component it covers.

As noted above, in some embodiments, the indentations can cover multiple electrical components. For example, in one embodiment a single dimension can be configured to cover all the electrical components disposed beneath the shield. In another embodiment, an indentation can be configured to cover only some of the components. Where a plurality of electrical components are disposed beneath the shield, an indentation may be disposed above only some of the components, while another indentation is disposed over other components, and some components have no indentation thereabove. However, in the embodiment of FIG. 5, the indentations correspond to electrical components on a one-to-one basis. This is evidenced by the fact that one indentation, e.g., indentation 408, covers one electrical component, e.g., integrated circuit processor 605.

The bottom surface 412 is disposed adjacent to an upper face 608 of the integrated circuit processor 605. In this embodiment, the bottom surface 412 is adjacent to, but does not touch, the upper face 608 of the integrated circuit processor 605. Instead, the bottom surface 412 and upper face 608 define a gap 609 therebetween. The dimensions of the gap 609 can vary based on application. In one embodiment shown to work well in mobile communication applications, the gap 609 is between 0.05 and 0.10 millimeters. For example, in one embodiment the gap 609 can be about 0.08 millimeters.

Turning to FIG. 7, the substrate 601 is being subjected to mechanical loading. The mechanical loading attempts to cause the substrate 601 to flex much as the circuit board (200) of FIG. 3 above did. However, the incorporation of the indentation 408 into the shield 400 works to limit the vertical translation by providing a mechanical stop for the integrated circuit processor 605. Specifically, the bottom surface 412 provides a mechanical stop for the upper face 608 of the integrated circuit processor 605. As the initial gap (609) was a small as 0.05 millimeters, vertical translation is limited to this amount. This is in contrast to prior art designs where the vertical translation can be ten to twenty times this amount.

Limiting the vertical translation increases the performance reliability of the assembly 600. In contrast to FIG. 3 above, none of the electrical connections have been compromised. The shield 400 has not been broken from the board, and the electronic components have not been damaged. Additionally, the indentations 408 of the shield 400 provide added rigidity to the overall shield structure to support the assembly, thereby allowing and development of thinner assemblies without risk of damage to the electrical components.

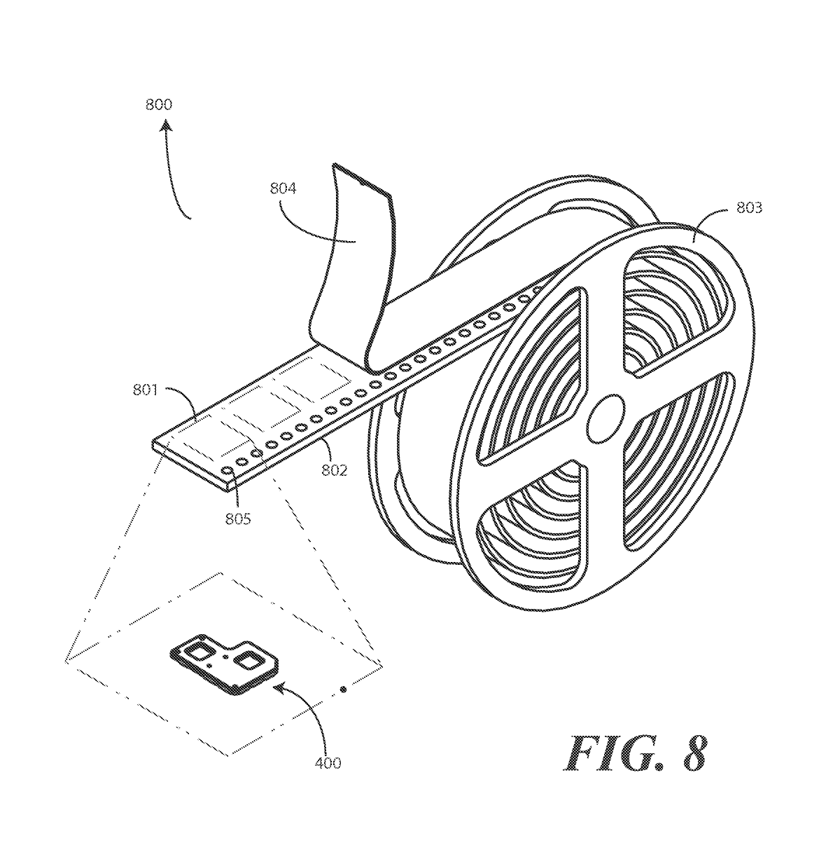

Turning now to FIG. 8, illustrated therein is illustrative packaging suitable for use with the shield 400 in compact electronic applications. As shown in FIG. 8, in one embodiment, the shield 400 can be packaged and dispensed from a tape and reel package 800. Tape and reel provides a suitable packaging for the shield 400 where an area of one of the upper surface (401) or the indentations (408,409) is sufficient for rapid picking and placing by industrial pick and place machines. A tape and reel package 800 can be modified to carry a plurality of shields within each dispensing area 801 or individual cells. The tape and reel package 800 can include a tape 802 carried by a reel 803 with a number of dispensing areas disposed along the tape 802. The tape 802 can be covered by a cover strip 804. The shields disposed in the tape 802 can progress and be dispensed in a pick and place machine using a series of sprockets or holes 805 to move the tape 802 along as needed. In one embodiment, the shields are packaged in the individual cells to avoid damage and/or contamination.

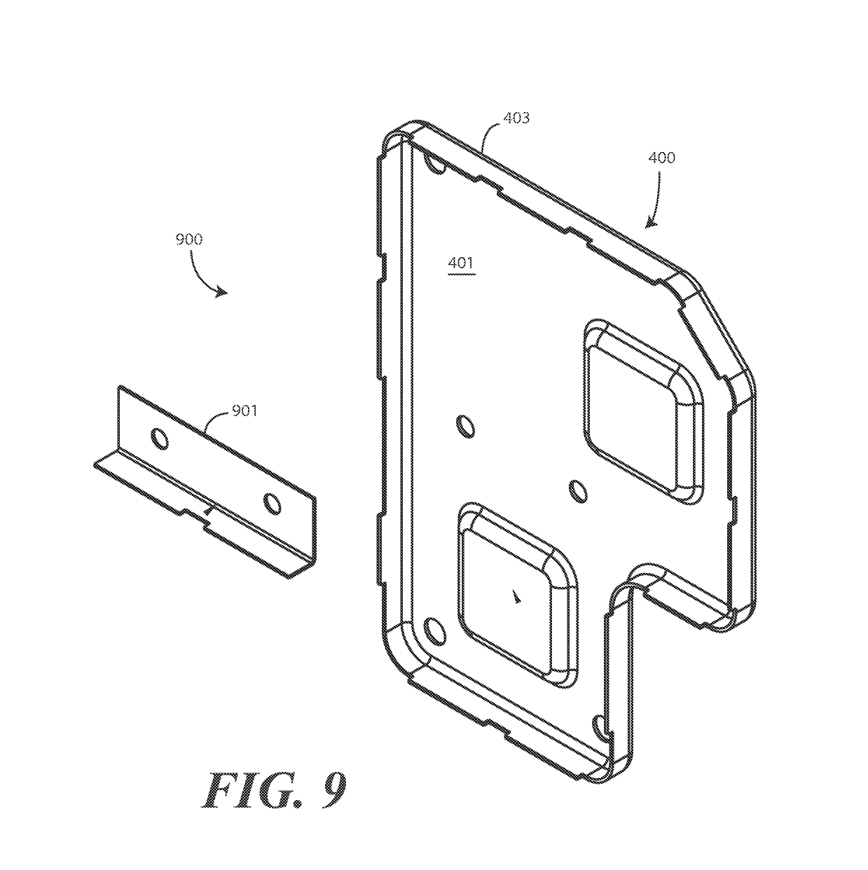

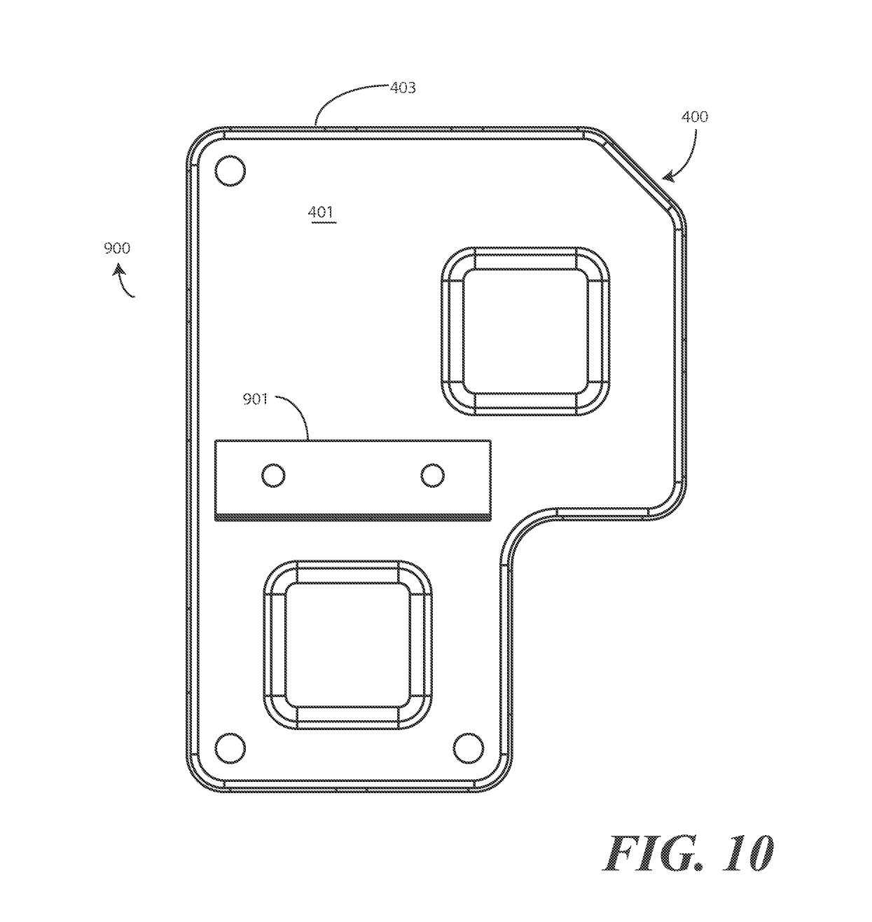

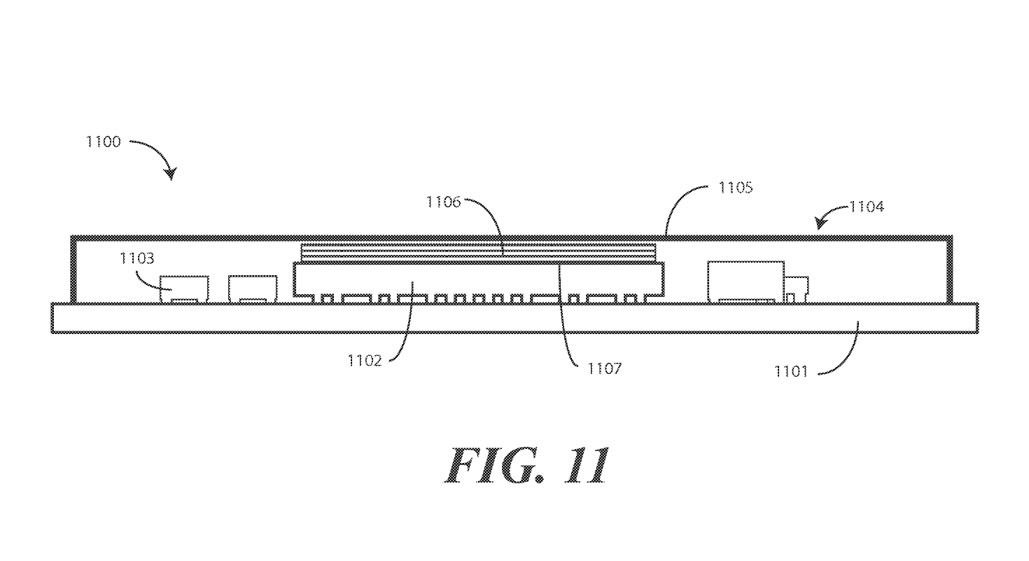

Turning now to FIGS. 9 and 10, illustrated therein is an alternate shield assembly 900 that includes a shield 400 and a partition 901. While one partition 901 is shown for illustration, embodiments of the disclosure can include multiple partitions as well. Moreover, while the partition 901 of FIGS. 9 and 10 is shown as mechanically connected to the shield 400, in other embodiments the partition 901 can be integrally formed with the shield.

The partition 901 can be used to provide shielding between components disposed beneath the shield 400. In this illustrative embodiment, the partition 901 extends from the upper surface 401 toward the substrate (not shown in FIG. 9) within a outer perimeter 403 of the shield 400. Since the partition 901 is a separate component in this embodiment, it can be manufactured from the same material as the shield 400 or from a different material. For example, the shield 400 can be cold rolled steel while the partition 901 is a metal screen or metal foam. Alternatively, both the shield 400 and the partition 901 can be manufactured from a common material, such as cold rolled steel. The partition 901 can be coupled to the shield 400 in a variety of ways. For example, in one embodiment the partition 901 is welded to the shield 400.

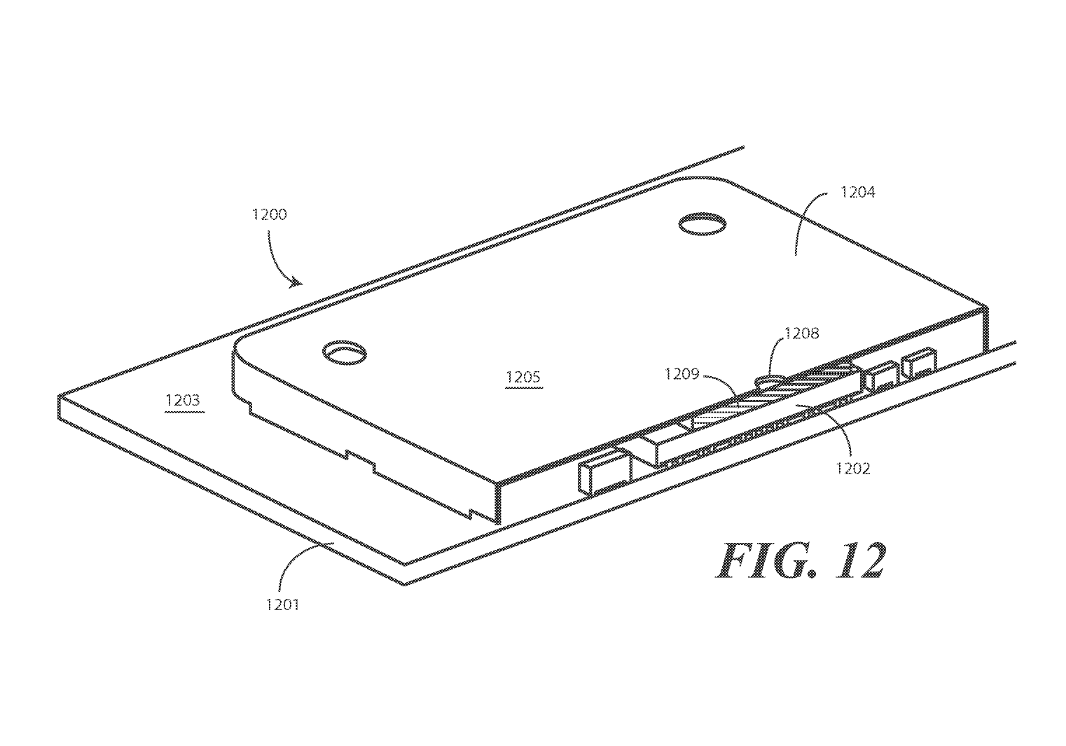

To this point, indentations have been described as providing the mechanical stops to prevent substrate translation due to the trampoline effect. Turning now to FIGS. 11 and 12, illustrated therein are alternate embodiments that use different technologies to provide mechanical stops for the electrical components disposed beneath corresponding shields.

Beginning with FIG. 11, this assembly 1100 includes a substrate 1101, one or more electrical components 1102 disposed along a major face 1103 of the substrate 1101, and a shield 1104 disposed along the major face 1103 of the substrate 1101 and enclosing the electrical component 1102. In this embodiment, rather than including indentations, the shield 1104 has an upper surface 1105 that is substantially planar. However, the embodiment of FIG. 11 can include some indentations as well.

To provide mechanical stability (in addition to any indentations that may be included), a shim 1106 having a size corresponding a top surface 1107 of the electrical component 1102 is disposed between the electrical component 1102 and the shield 1104. The shim 1106 can be formed from plastic, foam, or other suitable materials. The shim 1106 functions substantially in the same manner as the indentations (408,409) described above.

In FIG. 12, the assembly 1200 includes a substrate 1201, one or more electrical components 1202 disposed along a major face 1203 of the substrate 1201, and a shield 1204 disposed along the major face 1203 of the substrate 1201 and enclosing the electrical component 1202. In this embodiment, rather than including indentations, the shield 1204 has an upper surface 1205 that is substantially planar. However, the embodiment of FIG. 12 can include some indentations as well.

To provide mechanical stability (in addition to any indentations that may be included), a fill hole 1208 is configured in the shield 1204 above the electrical component 1202. Rather than placing a mechanical shim or other device between the upper surface 1205 and the electrical component 1202, the fill hole 1208 allows an epoxy, resin, polymer or other material 1209 to be injected between the electrical component 1202 and the shield 1024. Placement of the fill hole 1208 over the electrical component advantageously allows the epoxy, resin, polymer or other material 1209 to be placed only along the upper surface of the electrical component, rather than everywhere under the shield 1204. The epoxy, resin, polymer or other material 1209 functions substantially in the same manner as the indentations (408,409) described above.

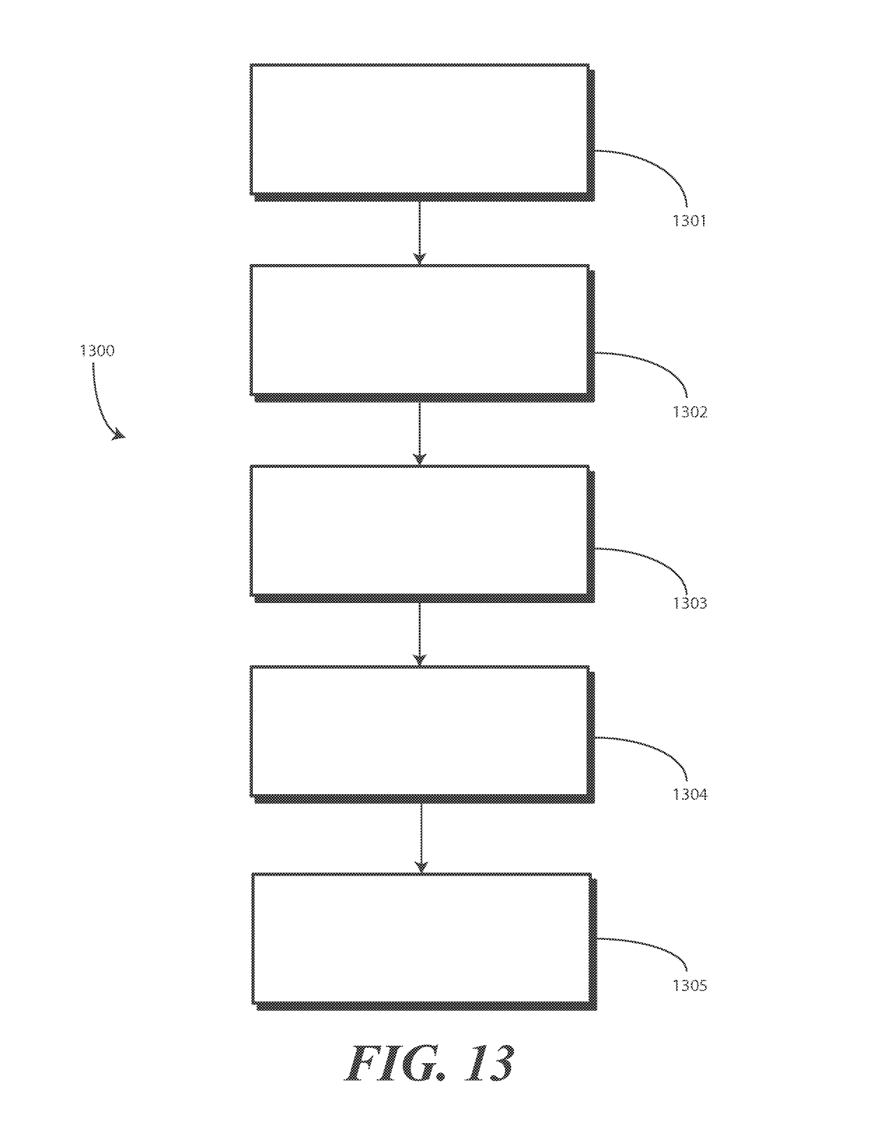

Turning to FIG. 13, illustrated therein is one explanatory method 1300 for manufacturing one or more assemblies configured in accordance with one or more embodiments of the disclosure. Many of the steps have largely been described above by way of the assemblies themselves, and accordingly will only briefly be described here.

At step 1301, the method 1300 places an electrical component on a substrate. At step 1302, the method 1300 places a shield on the substrate over the electrical component. In one embodiment, the shield has reduced headroom over the electrical component than over other electrical components disposed on the substrate under the shield. The reduced headroom can be the result of any of forming indentations in the shield, placing a shim beneath the shield, filling an epoxy, resin, polymer, or other material under the shield, or combinations thereof. For example, in one embodiment, shown illustratively at step 1303, the method 1300 forms one or more indentations in an upper surface of the shield extending toward the electrical component, thereby creating the reduced headroom.

In another embodiment, shown illustratively at step 1304, the method 1300 provides a shim between the shield and the electrical component, thereby creating the reduced headroom. In another embodiment, shown illustratively at step 1305, the method 1300 fills an epoxy, resin, polymer, or other material through a fill hole between the electrical component and the shield. Note that steps 1303,1304,1305 can be performed independently, e.g., performing step 1304 and not steps 1303,1305, or in combination, e.g., performing steps 1303 and 1303, but not step 1304, or alternatively performing all steps. For example, where steps 1303 and 1305 are both performed, the shield can define a fill hole disposed above the electrical component, and also one or more indentations disposed above, and extending toward, the electrical component from the upper surface. The fill hole can be disposed in an indentation, and a shim can be formed by injecting a polymer into the fill hole. Other variations will be obvious to those of ordinary skill in the art having the benefit of this disclosure.

In the foregoing specification, specific embodiments of the present disclosure have been described. However, one of ordinary skill in the art appreciates that various modifications and changes can be made without departing from the scope of the present disclosure as set forth in the claims below. Thus, while preferred embodiments of the disclosure have been illustrated and described, it is clear that the disclosure is not so limited. Numerous modifications, changes, variations, substitutions, and equivalents will occur to those skilled in the art without departing from the spirit and scope of the present disclosure as defined by the following claims. Accordingly, the specification and figures are to be regarded in an illustrative rather than a restrictive sense, and all such modifications are intended to be included within the scope of present disclosure. The benefits, advantages, solutions to problems, and any element(s) that may cause any benefit, advantage, or solution to occur or become more pronounced are not to be construed as a critical, required, or essential features or elements of any or all the claims.

What is claimed is:

1. An assembly, comprising
a substrate;
at least one electrical component disposed along a major face of the substrate; and
a shield disposed along the major face and enclosing the at least one electrical component, the shield having an upper surface comprising one or more indentations disposed above, and extending toward, the at least one electrical component from the upper surface.

2. The assembly of claim 1, each indentation having a length and a width corresponding to that of the at least one electrical component.

3. The assembly of claim 1, the one or more indentations corresponding to electrical components on a one-to-one basis.

4. The assembly of claim 1, each indentation having a substantially rectangular perimeter.

5. The assembly of claim 1, each indentation having a bottom surface disposed adjacent to an upper face of the at least one electrical component.

6. The assembly of claim 5, the bottom surface and the upper face defining a gap therebetween.

7. The assembly of claim 6, the gap between 0.05 and 0.10 millimeters.

8. The assembly of claim 1, each indentation comprising radiused sidewalls.

9. The assembly of claim 1, the shield comprising at least one partition extending from the upper surface toward the substrate within a perimeter of the shield.

10. The assembly of claim 1, the shield manufactured from cold rolled steel.

11. The assembly of claim 1, the at least one electrical component comprising a plurality of electrical components, the one or more indentions disposed only above some of the plurality of electrical components.

12. An assembly, comprising:
a substrate;
an electrical component disposed along a major face of the substrate;
a shield disposed along the major face and enclosing the electrical component; and
a shim having a size corresponding a top surface of the electrical component disposed between the electrical component and the shield.

13. The assembly of claim 12, the shim comprising plastic.

14. The assembly of claim 12, the shim comprising foam.

15. The assembly of claim 12, the shield defining a fill hole disposed above the electrical component, the shim comprising a polymer injected through the fill hole.

16. The assembly of claim 12, the shield having an upper surface comprising one or more indentations disposed above, and extending toward, the electrical component from the upper surface.

17. The assembly of claim 16, the shield defining a fill hole disposed in an indentation, the shim comprising a polymer injected through the fill hole.

18. A method for manufacturing an assembly, comprising:
placing an electrical component on a substrate; and
placing a shield on the substrate over the electrical component, the shield having a reduced headroom over the electrical component than over other electrical components disposed on the substrate under the shield.

19. The method of claim 18, further comprising forming one or more indentations in an upper surface of the shield extending toward the electrical component, thereby creating the reduced headroom.

20. The method of claim 18, further comprising providing a shim between the shield and the electrical component, thereby creating the reduced headroom.
